(19) United States
(12) Patent Application Publication
(10) Pub. No.: US 2004/0180277 A1
(43) Pub. Date: Sep. 16, 2004

(54) Substrate treating method and apparatus

(75) Inventors: Masahiko Harumoto, Kyoto (JP); Masakazu Sanada, Kyoto (JP)

Correspondence Address: OSTROLENK FABER GERB & SOFFEN, 1180 AVENUE OF THE AMERICAS, NEW YORK, NY, 100368403

(73) Assignee: Dainippon Screen Mfg. Co., Ltd.

(21) Appl. No.: 10/715,817

(22) Filed: Nov. 17, 2003

(30) Foreign Application Priority Data
Nov. 18, 2002 (JP) 2002-333503

(51) Int. Cl. G03F 7/00

(52) U.S. Cl. 430/30; 430/322; 430/330

(57) ABSTRACT

An actual pattern size is obtained from a processing carried out at a pivotal point which is an exposing condition resulting in little variation in pattern size even with variations in focus of exposing light. An operation is inputted on a switching screen displayed for selecting whether to set a substrate treating condition according to a pivotal shift which is a difference between the actual pattern size and a mask pattern size. When setting a substrate treating condition according to the pivotal shift, an operation is inputted on a type selecting screen displayed for selecting a type from different types of substrate treating conditions including the types of photoresist, the types of pattern size and the types of pattern form. Then, an operation is inputted on a substrate treating condition selecting screen displayed for selecting one substrate treating condition from a plurality of substrate treating conditions of the same type selected on the type selecting screen. An optimal developing time is derived from a correlation between a developing time with the selected substrate treating condition and the pivotal shift, whereby a pattern size may be set simply.

### BACKGROUND OF THE INVENTION

(1) Field of the Invention

This invention relates to a substrate treating method and apparatus for treating substrates such as semiconductor wafers, glass substrates for liquid crystal displays, glass substrates for photomasks, and substrates for optical disks (hereinafter called simply “substrates”). More particularly, the invention relates to a technique for forming patterns on substrates by coating the substrates with a film of chemically amplified photoresist, exposing the substrates having the photoresist film formed thereon, and developing the exposed substrates.

(2) Description of the Related Art

In order to form a pattern on a substrate in conventional substrate treatment, a mask pattern is set to the substrate having a coating film (e.g. photoresist film), the substrate is exposed to light emitted through the mask pattern, and then the exposed substrate is developed. In practice, irregularities exist on the surface of the substrate, which cause focal changes in different positions on the substrate. The focal changes result in varied pattern sizes actually obtained in different positions on the substrate.

Pattern size is variable with light exposure as well as focus. When a certain exposure value is selected, there is a condition in which little variation occurs in pattern size even with focal changes. In this specification, this condition is defined as “pivotal point”. With the pivotal point adopted as an exposing condition, a uniform pattern size may be obtained even when focal changes are caused by the irregularities on the surface of the substrate.

However, a difference occurs between a mask pattern size and an actual pattern size obtained from a processing with the pivotal point. In this specification, the difference between the mask pattern size and the actual pattern size obtained from a processing with the pivotal point is defined as “pivotal shift”. Conventionally, therefore, a shift is applied to the mask pattern for correction in order to obtain a desired pattern size after exposure.

It is known, however, that in practice pattern size and pivotal shift do not have a proportional relationship therebetween. Even when the pattern size is corrected by an amount of pivotal shift, a new pivotal shift will occur to the corrected pattern size. It is difficult to obtain a desired pattern size at a point of zero pivotal shift. Moreover, even if one pattern size is successfully corrected, a desired pattern size cannot be obtained by using the same correction for a different pattern size.

In Japanese Unexamined Patent Publication No. 7-168341 (1995), a solution to the above problem is proposed. The solution is based on an assumption that the correlation between pattern size and pivotal shift approximates a straight line in minute regions. A pattern size with zero pivotal shift is determined by using triangular similarities among a mask pattern size, a pivotal shift corresponding to the mask pattern size, a pivotal shift resulting from the pattern size corrected with the pivotal shift, a pivotal shift corresponding to the corrected pattern size, and so on.

However, such a pattern size correction that reduces the pivotal shift to zero requires a corrected mask pattern for each pattern size. Furthermore, since the amount of pivotal shift is variable with the type of photoresist, corrected mask patterns are needed for each resist type, resulting in an enormous number of masks. The numerous mask patterns for each pattern size and each resist type entail an extraordinary processing time and cost.

### SUMMARY OF THE INVENTION

This invention has been made having regard to the state of the art noted above, and its object is to provide a substrate treating method and apparatus for setting a pattern size simply.

To fulfill the above object, Inventors have made intensive research and attained the following findings.

Conventionally, a mask pattern has been controlled to correct the pattern size so that the pivotal shift may be reduced to zero. Inventors have now adopted a different approach, and attempts have been made to effect controls with other substrate treating conditions that influence the pattern size, with little or no control done on the mask pattern.

A pivotal shift tends to occur with what is called a “chemically amplified resist” in particular among the coating solutions for forming coating film on substrates. The chemically amplified resist contains an acid generating agent as a sensitizing agent. The acid generated by exposure induces a catalytic reaction in a heating treatment that follows, to promote insolubilization of a negative developer and solubilization of a positive developer. While it is difficult to modify the chemically amplified resist itself, various experiments have been conducted on the assumption that a pattern size may be changed, depending on a substrate treating condition relating to an acid diffusion represented by a diffusion length indicative of a spread of the acid generated by exposure. On the other hand, various experiments have been conducted on the assumption that a pattern size may be changed, depending on a substrate treating condition relating to a dissolving rate of the resist in a developing process.

Substrate treating conditions have been varied for heating treatment before or after exposure, or for developing treatment, for example. As a result, it has been confirmed that, under certain conditions, changes take place in the pivotal shift and the latter may be reduced to zero without correcting pattern size. Then, what is necessary is only to set a pattern size simply by controlling the substrate treating condition relating to acid diffusion or substrate treating condition relating to dissolving rate.

Based on the above findings, this invention provides a substrate treating method for performing a series of substrate treating processes to form a pattern on a substrate by forming a coating film of a chemically amplified photoresist on the substrate, exposing the substrate having the coating film formed thereon, and developing the exposed substrate, the method comprising the steps of:

controlling a substrate treating condition relating to acid diffusion that influences spread of an acid produced in the coating film by exposure of the coating film, according to a pivotal shift which is a difference between an actual pattern size and a mask pattern size, the actual pattern size being obtained from a processing carried out at a pivotal point which is an exposing condition resulting in little variation in pattern size even with variations in focus of exposing light; and

performing the series of substrate treating processes based on the substrate treating condition relating to acid diffusion as controlled.

With the substrate treating method according to this invention, a substrate treating condition relating to acid diffusion is controlled, and the series of substrate treating processes is performed based on the substrate treating condition relating to acid diffusion as controlled. Thus, a pattern may be set simply with little or no control done on the mask pattern.

In another aspect of the invention, a substrate treating method is provided for performing a series of substrate treating processes to form a pattern on a substrate by forming a coating film of a chemically amplified photoresist on the substrate, exposing the substrate having the coating film formed thereon, and developing the exposed substrate, the method comprising the steps of:

controlling a substrate treating condition relating to dissolving rate that influences a dissolving rate of the coating film by development, according to a pivotal shift which is a difference between an actual pattern size and a mask pattern size, the actual pattern size being obtained from a processing carried out at a pivotal point which is an exposing condition resulting in little variation in pattern size even with variations in focus of exposing light; and

performing the series of substrate treating processes based on the substrate treating condition relating to dissolving rate as controlled.

With the substrate treating method according to this invention, a substrate treating condition relating to dissolving rate is controlled, and the series of substrate treating processes is performed based on the substrate treating condition relating to dissolving rate as controlled. Thus, a pattern may be set simply with little or no control done on the mask pattern.

In a further substrate treating method, according to this invention, for performing a series of substrate treating processes to form a pattern on a substrate by forming a coating film of a chemically amplified photoresist on the substrate, exposing the substrate having the coating film formed thereon, and developing the exposed substrate, the method comprises the steps of:

controlling a substrate treating condition relating to acid diffusion that influences spread of an acid produced in the coating film by exposure of the coating film, according to a pivotal shift which is a difference between an actual pattern size and a mask pattern size, the actual pattern size being obtained from a processing carried out at a pivotal point which is an exposing condition resulting in little variation in pattern size even with variations in focus of exposing light, and controlling a substrate treating condition relating to dissolving rate that influences a dissolving rate of the coating film by development, according to the pivotal shift; and

performing the series of substrate treating processes based on the substrate treating condition relating to acid diffusion and the substrate treating condition relating to dissolving rate as controlled.

With the substrate treating method according to this invention, a substrate treating condition relating to acid diffusion and a substrate treating condition relating to dissolving rate are controlled, and the series of substrate treating processes is performed based on the substrate treating conditions relating to acid diffusion and dissolving rate as controlled. Thus, a pattern may be set simply with little or no control done on the mask pattern.

The above substrate treating condition relating to acid diffusion may be a substrate treating condition relating to pre-exposure heating that influences heating of the coating film before the exposure, or a substrate treating condition relating to post-exposure heating that influences heating of the coating film after the exposure.

The substrate treating condition relating to pre-exposure heating may, for example, be a heating time of the coating film before the exposure, a heating temperature of the coating film before the exposure. The substrate treating condition relating to post-exposure heating may be a heating time of the coating film after the exposure, or a heating temperature of the coating film after the exposure.

It has been confirmed through experiment that, with a high heating temperature of the coating film before the exposure, the substrate is tightened, thereby hampering diffusion of the acid in time of exposure. In the case of the negative type, the pivotal shift decreases to zero and then increases in the negative direction. It has also been confirmed through experiment that, with a high heating temperature of the coating film after the exposure, the acid produced by exposure promotes a catalytic reaction, and thus diffusion of the acid. In the case of the negative type, the pivotal shift increases from the negative direction to zero and then increases in the positive direction.

The substrate treating condition relating to dissolving rate may, for example, be a temperature in a developing atmosphere, a humidity in the developing atmosphere, a concentration of a developing solution, a temperature of the developing solution, or a developing time. It has been confirmed through experiment that, with an extension of the developing time, for example, the pivotal shift increases from the negative direction to become zero, and increases in the positive direction.

To set a pattern without controlling the mask pattern, it is preferable to control the substrate treating condition relating to acid diffusion or the substrate treating condition relating to dissolving rate to reduce the pivotal shift to zero.

In a further aspect of the invention, a substrate treating apparatus is provided for performing a series of substrate treating processes to form a pattern on a substrate by forming a coating film on the substrate, exposing the substrate having the coating film formed thereon, and developing the exposed substrate, the apparatus comprising:

a switching device for selecting whether to set a substrate treating condition according to a pivotal shift which is a difference between an actual pattern size and a mask pattern size, the actual pattern size being obtained from a processing carried out at a pivotal point which is an exposing condition resulting in little variation in pattern size even with variations in focus of exposing light;

wherein the series of substrate treating processes is performed based on the substrate treating condition selected or a substrate treating condition deselected by the switching device.

The substrate treating apparatus according to this invention includes a switching device for selecting whether to set a substrate treating condition according to a pivotal shift. The series of substrate treating processes may be performed based on a substrate treating condition selected or a substrate treating condition deselected by the switching device. Where, for example, the coating solution does not produce a pivotal shift or a pivotal shift, if at all, does not adversely influence variations in pattern size, there is no need to set a substrate treating condition according to the pivotal shift. Thus, a substrate treating apparatus with increased flexibility is realized for executing the series of substrate treating processes for patterning the substrate by forming a coating film on the substrate, exposing the coated substrate, and developing the exposed substrate.

A different substrate treating apparatus is provided according to this invention for performing a series of substrate treating processes to form a pattern on a substrate by forming a coating film on the substrate, exposing the substrate having the coating film formed thereon, and developing the exposed substrate, the apparatus comprising:

a substrate treating condition selecting device for selecting one substrate treating condition from a plurality of substrate treating conditions of the same type; and

a correlation storage device for storing correlations between a plurality of substrate treating conditions, a pivotal shift which is a difference between an actual pattern size and a mask pattern size, the actual pattern size being obtained from a processing carried out at a pivotal point which is an exposing condition resulting in little variation in pattern size even with variations in focus of exposing light, a substrate treating condition relating to acid diffusion that influences spread of an acid produced in the coating film by exposure of the coating film, and a substrate treating condition relating to dissolving rate that influences a dissolving rate of the coating film by development;

wherein the series of substrate treating processes is performed based on the substrate treating condition selected by the substrate treating condition selecting device and the correlations read from the correlation storage device.

The above substrate treating apparatus according to this invention includes the substrate treating condition selecting device for selecting one substrate treating condition from a plurality of substrate treating conditions of the same type, and the correlation storage device for storing correlations between a plurality of substrate treating conditions, a pivotal shift, a substrate treating condition relating to acid diffusion, and a substrate treating condition relating to dissolving rate. A correlation between the pivotal shift in the substrate treating condition selected by the substrate treating condition selecting device and the substrate treating condition relating to acid diffusion or substrate treating condition relating to dissolving rate is known from the selected substrate treating condition and the correlations read from the correlation storage device. Based on the correlation between the pivotal shift and the substrate treating condition relating to acid diffusion or dissolving rate, it is possible to control the substrate treating condition relating to acid diffusion or substrate treating condition relating to dissolving rate. A pattern size may be set simply in the series of substrate treating processes.

A further substrate treating apparatus is provided according to this invention for performing a series of substrate treating processes to form a pattern on a substrate by forming a coating film on the substrate, exposing the substrate having the coating film formed thereon, and developing the exposed substrate, the apparatus comprising:

a type selecting device for selecting at least one type from different types of substrate treating conditions;

a substrate treating condition selecting device for selecting one substrate treating condition from a plurality of substrate treating conditions of the same type selected by the type selecting device; and

a correlation storage device for storing correlations between a plurality of substrate treating conditions, a pivotal shift which is a difference between an actual pattern size and a mask pattern size, the actual pattern size being obtained from a processing carried out at a pivotal point which is an exposing condition resulting in little variation in pattern size even with variations in focus of exposing light, a substrate treating condition relating to acid diffusion that influences spread of an acid produced in the coating film by exposure of the coating film, and a substrate treating condition relating to dissolving rate that influences a dissolving rate of the coating film by development;

wherein the series of substrate treating processes is performed based on the substrate treating condition selected by the substrate treating condition selecting device and the correlations read from the correlation storage device, the substrate treating condition selecting device for selecting one substrate treating condition from a plurality of substrate treating conditions of the same type selected by the type selecting device, and

The above substrate treating apparatus according to this invention includes the type selecting device for selecting at least one type from different types of substrate treating conditions, the substrate treating condition selecting device for selecting one substrate treating condition from a plurality of substrate treating conditions of the same type, and the correlation storage device for storing correlations between a plurality of substrate treating conditions, a pivotal shift, a substrate treating condition relating to acid diffusion, and a substrate treating condition relating to dissolving rate. A correlation between the pivotal shift in the substrate treating condition selected by the substrate treating condition selecting device and the substrate treating condition relating to acid diffusion or substrate treating condition relating to dissolving rate is known from the selected substrate treating condition and the correlations read from the correlation storage device. Based on the correlation between the pivotal shift and the substrate treating condition relating to acid diffusion or dissolving rate, it is possible to control the substrate treating condition relating to acid diffusion or substrate treating condition relating to dissolving rate. A pattern size may be set simply in a series of substrate treating processes.

In a further aspect of the invention, a substrate treating apparatus is provided for performing a series of substrate treating processes to form a pattern on a substrate by forming a coating film on the substrate, exposing the substrate having the coating film formed thereon, and developing the exposed substrate, the apparatus comprising:

a switching device for selecting whether to set a substrate treating condition according to a pivotal shift which is a difference between an actual pattern size and a mask pattern size, the actual pattern size being obtained from a processing carried out at a pivotal point which is an exposing condition resulting in little variation in pattern size even with variations in focus of exposing light;

a substrate treating condition selecting device for selecting one substrate treating condition from a plurality of substrate treating conditions of the same type; and

a correlation storage device for storing correlations between a plurality of substrate treating conditions, the pivotal shift, a substrate treating condition relating to acid diffusion that influences spread of an acid produced in the coating film by exposure of the coating film, and a substrate treating condition relating to dissolving rate that influences a dissolving rate of the coating film by development;

wherein the series of substrate treating processes is performed based on the substrate treating condition selected or a substrate treating condition deselected by the switching device; and

wherein, when the substrate treating conditions are switched by the switching device, the series of substrate treating processes is performed based on the substrate treating condition selected by the substrate treating condition selecting device and the correlations read from the correlation storage device.

The above substrate treating apparatus according to this invention includes the switching device for selecting whether to set a substrate treating condition according to a pivotal shift. The series of substrate treating processes is performed based on the substrate treating condition selected or a substrate treating condition deselected by the switching device. The apparatus further includes the substrate treating condition selecting device for selecting one substrate treating condition from a plurality of substrate treating conditions of the same type, and the correlation storage device for storing correlations between a plurality of substrate treating conditions, a pivotal shift, a substrate treating condition relating to acid diffusion, and a substrate treating condition relating to dissolving rate. When substrate treating conditions are switched by the switching device, a correlation between the pivotal shift in the substrate treating condition selected by the substrate treating condition selecting device and the substrate treating condition relating to acid diffusion or substrate treating condition relating to dissolving rate is known from the selected substrate treating condition and the correlations read from the correlation storage device. Based on the correlation between the pivotal shift and the substrate treating condition relating to acid diffusion or dissolving rate, it is possible to control the substrate treating condition relating to acid diffusion or substrate treating condition relating to dissolving rate. A pattern size may be set simply in a series of substrate treating processes. Thus, a substrate treating apparatus with increased flexibility is realized for executing a series of substrate treating processes, with a pattern size set simply.

In a still further aspect of the invention, a substrate treating apparatus is provided for performing a series of substrate treating processes to form a pattern on a substrate by forming a coating film on the substrate, exposing the substrate having the coating film formed thereon, and developing the exposed substrate, the apparatus comprising:

a switching device for selecting whether to set a substrate treating condition according to a pivotal shift which is a difference between an actual pattern size and a mask pattern size, the actual pattern size being obtained from a processing carried out at a pivotal point which is an exposing condition resulting in little variation in pattern size even with variations in focus of exposing light;

a type selecting device for selecting at least one type from different types of substrate treating conditions;

a substrate treating condition selecting device for selecting one substrate treating condition from a plurality of substrate treating conditions of the same type selected by the type selecting device; and

a correlation storage device for storing correlations between a plurality of substrate treating conditions, the pivotal shift, a substrate treating condition relating to acid diffusion that influences spread of an acid produced in the coating film by exposure of the coating film, and a substrate treating condition relating to dissolving rate that influences a dissolving rate of the coating film by development;

wherein the series of substrate treating processes is performed based on the substrate treating condition selected or a substrate treating condition deselected by the switching device; and

wherein, when the substrate treating conditions are switched by the switching device, the series of substrate treating processes is performed based on the substrate treating condition selected by the substrate treating condition selecting device and the correlations read from the correlation storage device.

The above substrate treating apparatus according to this invention includes the switching device for selecting whether to set a substrate treating condition according to a pivotal shift. The series of substrate treating processes is performed based on the substrate treating condition selected or a substrate treating condition deselected by the switching device. The apparatus further includes the type selecting device for selecting at least one type from different types of substrate treating conditions, the substrate treating condition selecting device for selecting one substrate treating condition from a plurality of substrate treating conditions of the same type selected by the type selecting device, and the correlation storage device for storing correlations between a plurality of substrate treating conditions, a pivotal shift, a substrate treating condition relating to acid diffusion, and a substrate treating condition relating to dissolving rate. When substrate treating conditions are switched by the switching device, a correlation between the pivotal shift in the substrate treating condition selected by the substrate treating condition selecting device and the substrate treating condition relating to acid diffusion or substrate treating condition relating to dissolving rate is known from the selected substrate treating condition and the correlations read from the correlation storage device. Based on the correlation between the pivotal shift and the substrate treating condition relating to acid diffusion or dissolving rate, it is possible to control the substrate treating condition relating to acid diffusion or substrate treating condition relating to dissolving rate. A pattern size may be set simply in a series of substrate treating processes. Thus, a substrate treating apparatus with increased flexibility is realized for executing a series of substrate treating processes, with a pattern size set simply.

The type noted above may, for example, relate to a coating solution for forming the coating film on the substrate, to pattern size, or to pattern form.

After performing the series of substrate treating processes based on the correlations read from the correlation storage device, results of the processes may be stored in the correlation storage device, to reflect the results of the processes on a next series of substrate treating processes. This provides advantages of accumulating data relating to the correlations, and storing data corrected for increased accuracy.

### BRIEF DESCRIPTION OF THE DRAWINGS

For the purpose of illustrating the invention, there are shown in the drawings several forms which are presently preferred, it being understood, however, that the invention is not limited to the precise arrangement and instrumentalities shown.

FIG. 1 is a schematic plan view of a substrate treating apparatus according to the invention;

FIG. 2 is a schematic side view of a spin coater or spin developer in the treating apparatus;

FIG. 3 is a schematic side view of a prebake unit or postbake unit in the treating apparatus;

FIG. 4 is an explanatory view for illustrating a pivotal shift;

FIG. 5 is a schematic view showing a correlation between developing time and pivotal shift;

FIG. 6 is a schematic view of an input unit (touch panel) and adjacent components;

FIG. 7 is a flow chart showing a series of substrate treating processes according to the invention;

FIG. 8 is a flow chart showing an operation for setting an optimal developing time (control of developing time) before substrate treatment.

FIG. 9 is a view showing a display made on the touch panel;

FIG. 10 is a view showing a display made on the touch panel;

FIG. 11 is a view showing a display made on the touch panel;

FIG. 12 is a view showing a display made on the touch panel;

FIG. 13 is a view showing a display made on the touch panel;

FIG. 14 is a view showing a display made on the touch panel;

FIG. 15 is a view showing a display made on the touch panel;

FIG. 16 is a schematic view showing a modified correlation between developing time and pivotal shift; and

FIG. 17 is a schematic view showing another modified correlation between developing time and pivotal shift.

### DESCRIPTION OF THE PREFERRED EMBODIMENTS

Preferred embodiments of the invention will be described in detail hereinafter with reference to the drawings.

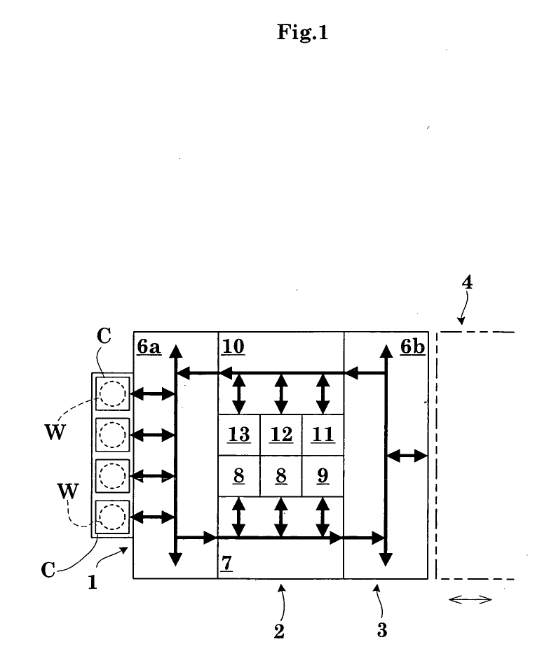

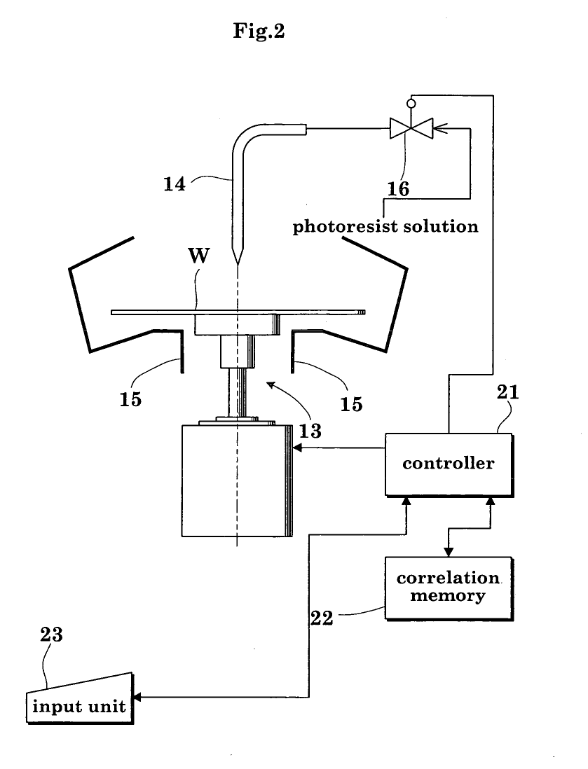

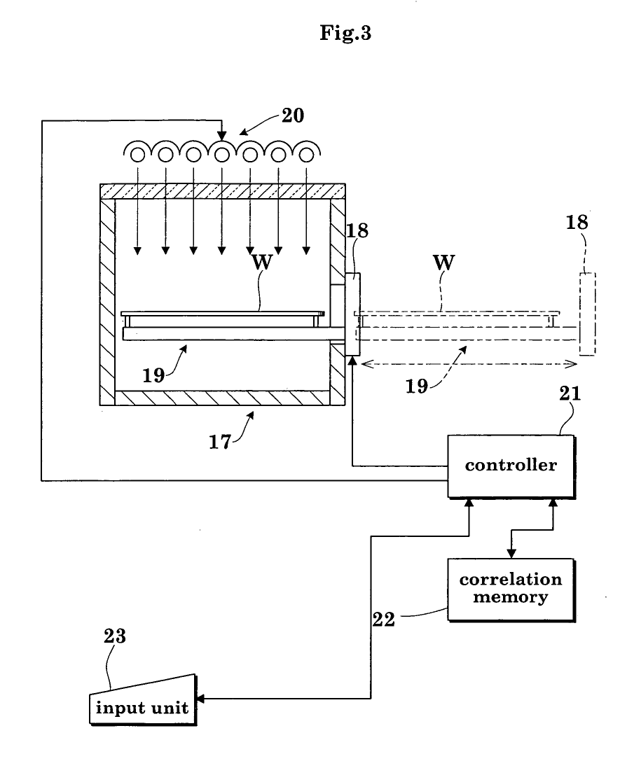

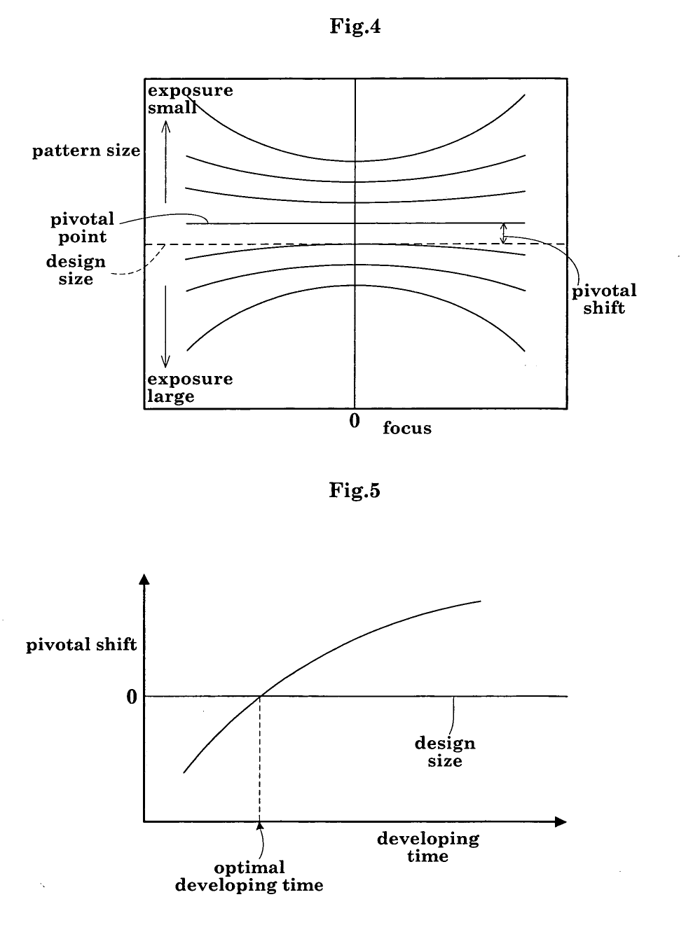

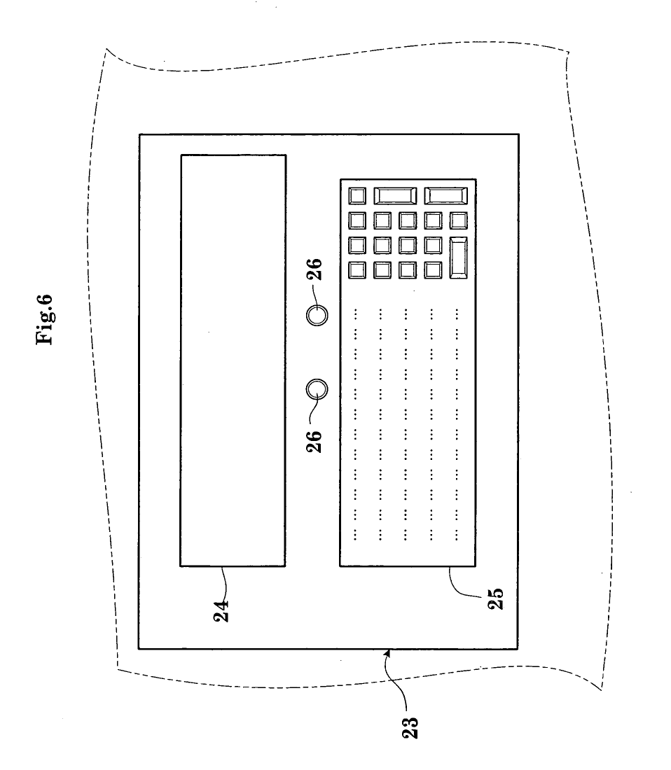

FIG. 1 is a schematic plan view of a substrate treating apparatus according to the invention. FIG. 2 is a schematic side view of a spin coater or spin developer in the treating apparatus. FIG. 3 is a schematic side view of a prebake unit or postbake unit in the treating apparatus. FIG. 4 is an explanatory view for illustrating a pivotal shift. FIG. 5 is a schematic view showing a correlation between developing time and pivotal shift. FIG. 6 is a schematic view of an input unit (touch panel) and adjacent components.

As shown in FIG. 1, the substrate treating apparatus in this embodiment includes an indexer 1, a processing unit 2 and an interface 3. In this embodiment, the interface 3 connects the processing unit 2 for performing resist application and development, and an exposing unit 4 acting as an external treating apparatus for exposing substrates (e.g. a stepper for performing step-and-repeat exposure).

A specific construction of the indexer 1 will be described next. The indexer 1 includes a cassette table 5, and an indexer's transport path 6a. The cassette table 5 is constructed for receiving thereon a plurality of (four in FIG. 1) cassettes C each containing a plurality of (e.g. 25) wafers W to be treated or wafers W already treated. An indexer's transport mechanism, not shown, is movable vertically, and horizontally on the transport path 6a in directions indicated by arrows in FIG. 1, for transferring the wafers W between the cassettes C on the cassette table 5 and the processing unit 2.

A specific construction of the interface 3 will be described next. The interface 3 includes an interface's transport path 6b similar to the indexer's transport path 6a. An interface's transport mechanism, not shown, is movable vertically, and horizontally on the transport path 6b in directions indicated by arrows in FIG. 1, for transferring the wafers W between the processing unit 2 and exposing unit 4.

A specific construction of the processing unit 2 will be described next. The processing unit 2 includes a forward transport path 7, a plurality of (two in FIG. 1) spin coaters 8, a prebake unit 9, a return transport path 10, a post-exposure bake unit 11 and a plurality of (two in FIG. 1) spin developers 12.

The spin coaters 8 are units for forming photoresist film on wafers W. The prebake unit 9 is a unit for heating wafers W having the photoresist film formed thereon. The forward transport path 7 extends between the indexer 1 and interface 3. A forward transport mechanism, not shown, is movable vertically, and horizontally on the transport path 7 in directions indicated by arrows in FIG. 1, to transfer wafers W between the indexer 1, spin coaters 8, prebake unit 9 and interface 3. The photoresist film corresponds to the coating film in this invention. Prebake is a heating treatment performed before exposure. Prebake corresponds to the pre-exposure heating in this invention.

Since this embodiment provides two spin coaters 8, one of the spin coaters 8 may be used to form a bottom anti-reflective coating on wafers W in order to prevent a reflection of light from the photoresist film formed on the wafers W, and the other used to form the photoresist film on the wafers W. At least one of the spin coaters 8 may have both the function for forming the anti-reflective coating and the function for forming the photoresist film.

The postbake unit 11 is a unit for heating wafers W after exposure. The spin developers 12 are units for developing wafers W after exposure and post-exposure heating. The return transport path 10, as does the forward transport path 7, extends between the indexer 1 and interface 3. A return transport mechanism, not shown, is movable vertically, and horizontally on the transport path 10 in directions indicated by arrows in FIG. 1, to transfer wafers W between the interface 3, postbake unit 11, spin developers 12 and indexer 1. Postbake corresponds to the post-exposure heating in this invention.

A specific construction of the spin coaters 8 will be described next. The spin developers 12 have the same construction as the spin coaters 8 except that a developing solution, instead of a photoresist solution, is directed to wafers W, and will not be described. As shown in FIG. 2, each spin coater 8 includes a spin chuck 13 for holding and spinning a wafer W in a horizontal plane, a nozzle 14 for delivering the photoresist solution, and a scatter preventive cup 15 for preventing scattering of the photoresist solution. The photoresist solution used herein is a chemically amplified resist solution. Though not shown, the spin coater 8 may further include an edge rinse nozzle for delivering a rinse solution as a cleaning liquid toward edges of wafer W to wash the photoresist solution and stains away from the edges, and a back rinse nozzle for delivering the rinse solution to the back side surface of wafer W to wash the photoresist solution and stains away from the back side surface.

The photoresist solution is delivered from the nozzle 14 toward the center of wafer W held and spun by the spin chuck 13. The centrifugal force of wafer W spreads the photoresist solution from the center to form a photoresist film over the entire surface of wafer W. In the developing treatment, the developing solution is delivered from the nozzle 14 toward the wafer W held and spun by the spin chuck 13.

An adjusting valve 16 is disposed between the nozzle 14 and a tank (not shown) storing the photoresist solution. A controller 21, to be described hereinafter, controls through the adjusting valve 16 the flow rate of the photoresist solution, and starting and stopping of the delivery of the photoresist solution. It is to be noted that the controller 21, correlation memory 22, and input unit 23 in FIG. 2 are the same as the controller 21, correlation memory 22, and input unit 23 in FIG. 3.

A specific construction of the prebake unit 9 will be described next. The postbake unit 11 has substantially the same construction as the prebake unit 9, and will not be described. As shown in FIG. 3, the prebake unit 9 includes a heat-treating furnace 17 having an opening formed in a side wall thereof and a light intake window on the top wall, a shutter 18 for closing the opening of the heat-treating furnace 17, a substrate holder 19 with support pins movable with horizontal movement of the shutter 18, and a lamp unit 20 for emitting light through the light intake window of heat-treating furnace 17 to heat (bake) a wafer W in the heat-treating furnace 17.

To load a wafer W for heat treatment, the wafer W is placed on the support pins to be held by the substrate holder 19, and the shutter 18 is moved horizontally toward the heat-treating furnace 17. To unload the wafer W after the heat treatment, the shutter 18 is moved horizontally away from the heat-treating furnace 17. To perform heat treatment for prebake (pre-exposure heating) and postbake (post-exposure heating), the lamp unit 20 emits light through the light intake window of heat-treating furnace 17 to the wafer W in the heat-treating furnace 17. Prebake is a heating treatment performed to evaporate a solvent in the photoresist film formed on the wafer W. Postbake is a heating treatment for inducing a catalytic reaction from an acid produced in the photoresist film by exposure, to carry out the developing process efficiently.

Specific constructions of the controller 21, correlation memory 22 and input unit (touch panel) 23 will be described next. The controller 21 performs an overall control of this apparatus. The correlation memory 22 is a memory, typically a RAM (Random Access Memory), storing correlations between a plurality of substrate treating conditions, pivotal shifts, substrate treating conditions relating to acid diffusion and substrate treating conditions relating to dissolving rate. The input unit 23 includes a pointing device such as a mouse, a keyboard, buttons and a touch panel. Based on data inputted by the operator, the controller 21 controls the components of the apparatus (e.g. the indexer 1, processing unit 2, interface 3 and so on).

In this embodiment, substrate treating conditions inputted and selected through the touch panel 24 of input unit 23 (FIGS. 6 and 9-15) are transmitted to the correlation memory 22 via the controller 21. Substrate treatment is carried out with a substrate treating condition relating to dissolving rate or substrate treating condition relating to acid diffusion that results in zero pivotal shift, in the selected substrate treating conditions. In this embodiment, substrate treating conditions other than the substrate treating conditions relating to acid diffusion or dissolving rate are combinations of the types of photoresist, the types of pattern size and the types of pattern shape. The substrate treating conditions relating to dissolving rate will be described by taking a developing time of developing treatment performed at each spin developer 12 for example.

FIG. 4 shows a relationship between focus and pattern size for a positive resist occurring with varied exposure values. The horizontal axis represents focus, and the vertical axis pattern size. Pattern size is the larger with the smaller exposure value, and the smaller with the larger exposure value. In FIG. 4, an exposure value (exposing condition) exists where the pattern size undergoes little change despite focal changes. This condition serves as a pivotal point, and a pivotal shift is expressed by a difference between pattern size and mask pattern size (design size in FIG. 4) at the pivotal point.

FIG. 5 schematically shows a correlation between pivotal shift and developing time. The horizontal axis represents developing time, and the vertical axis pivotal shift. This schematic view is variable with a plurality of substrate treating conditions consisting of combinations of the types of photoresist, the types of pattern size and the types of pattern shape. Conversely, when one substrate treating condition is selected for a particular type of photoresist, pattern size or pattern shape from the plurality of substrate treating conditions for various types of photoresist, pattern size and pattern shape, the schematic view shown in FIG. 5 is uniquely determined from that selected substrate treating condition.

When the pivotal shift is zero, the pattern size and mask pattern size (design size in FIG. 5) at the pivotal point are in agreement. It is unnecessary to control the mask pattern for correcting the pattern size at this time. Thus, the developing time at zero pivotal shift is the “optimal developing time” shown in FIG. 5. The correlation shown in FIG. 5 is stored in the correlation memory 22 for each of the plurality of substrate treating conditions consisting of combinations of the types of photoresist, types of pattern size and types of pattern shape. The correlation memory 22 corresponds to the correlation storage device in this invention.

As shown in FIG. 6, for example, the input unit 23 includes a touch panel 24, a keyboard 25 and buttons 26. In this embodiment, the touch panel 24 displays a type selecting screen for making a selection from the types of photoresist, the types of pattern size and the types of pattern shape, and a substrate treating condition selecting screen for selecting one substrate treating condition from a plurality of substrate treating conditions for the type selected on the type selecting screen. The operator directly touches the touch panel 24 to select a substrate treating condition and the like according to operational displays appearing on the touch panel 24. The touch panel 24 corresponds to the switching device, type selecting device and substrate treating condition selecting device in this invention.

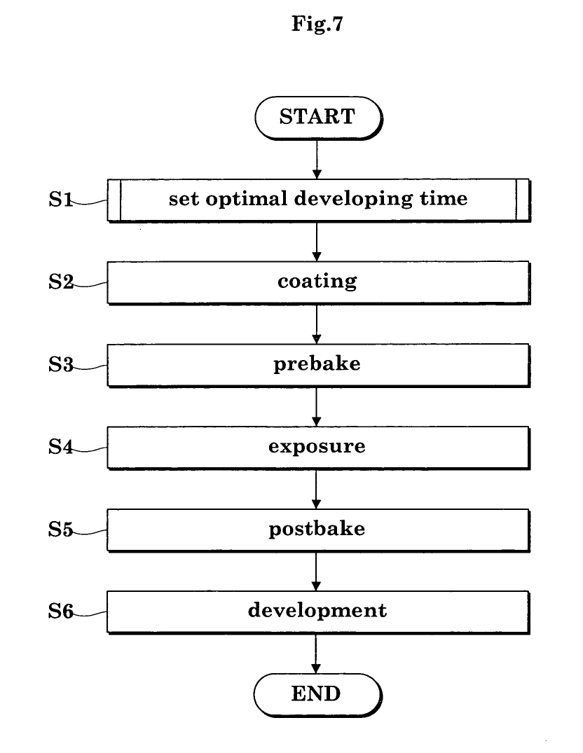

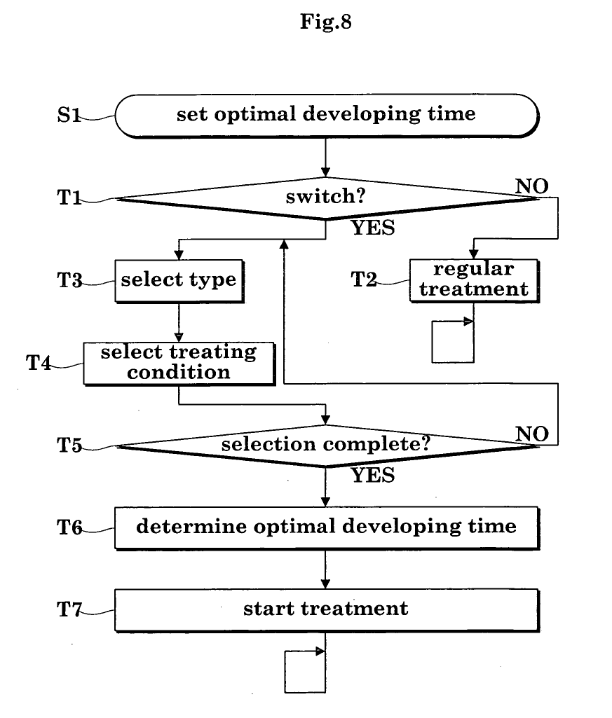

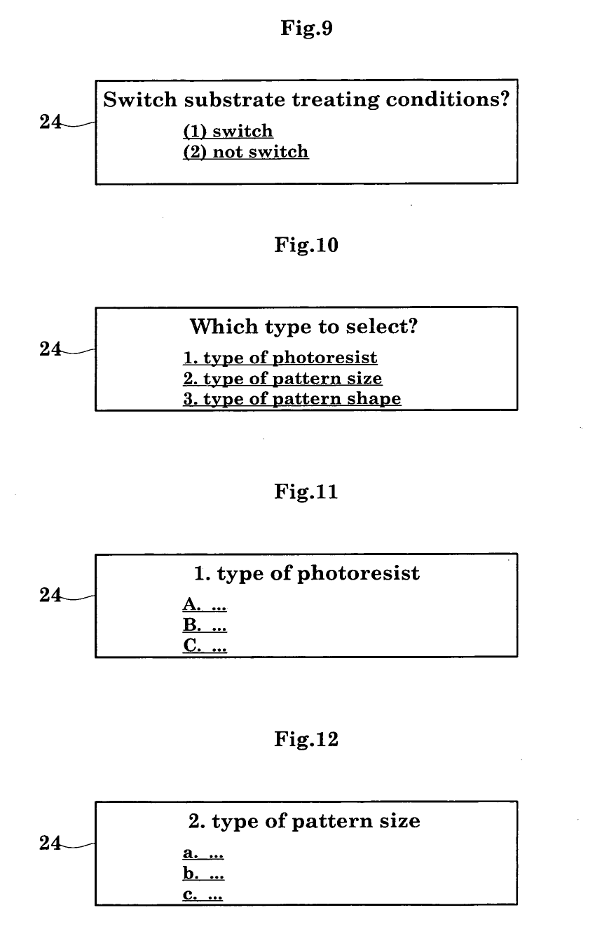

A series of substrate treating processes in this embodiment will be described next with reference to the flow chart shown in FIG. 7. A setting of the optimal developing time (control of the developing time) before substrate treatment will also be described with reference to the flow chart shown in FIG. 8 and the display modes shown in FIGS. 9 through 15. In this embodiment, what is set is a developing time. The setting operation may be carried out at any time before a developing process, which may be after exposure or post-exposure bake. Thus, no limitation is placed on timing of the setting of a developing time.

Step S1 (set optimal developing time):

An optimal developing time is set according to an operational display appearing on the touch panel 24. Specifically, this operation follows steps T1-T7.

Step T1 (switch?)

The operator determines whether to set a substrate treating condition according to a pivotal shift. Specifically, as shown in FIG. 9, the touch panel 24 displays a switching screen with a question “Switch substrate treating conditions?”, and displays options “(1) switch” and “(2) not switch” thereunder.

Step T2 (regular treatment)

Where the coating solution does not produce a pivotal shift (e.g. a photoresist other than a chemically amplified photoresist), or when the operator decides that a pivotal shift, if at all, will not adversely influence variations in pattern size, the operator touches the area of “(2) not switch”, indicating that a substrate treating condition is not to be set according to a pivotal shift. Then, the operation moves to regular treatment. The screen appearing on the touch panel 24 shown in FIG. 9 changes to a different screen not shown.

Step T3 (select type)

When the operator determines that a pivotal shift has occurred to influence adversely the variations in pattern size, the operator touches the area of “(1) switch” whereby the operation moves to a type selection. Then, the display mode of the touch panel 24 changes to what is shown in FIG. 10.

Specifically, as shown in FIG. 10, the touch panel 24 displays a type selecting screen with a question “Which type to select?”, and options “1. type of photoresist”, “2. type of pattern size” and “3. type of pattern shape” thereunder.

When a substrate treating condition is selected based on the type of photoresist, the operator touches the area of “1. type of photoresist” by way of type selection. Then, the display mode of the touch panel 24 changes to what is shown in FIG. 11.

Step T4 (select treating condition)

Specifically, as shown in FIG. 11, the touch panel 24 displays a substrate treating condition selecting screen for “1. type of photoresist”. Options “A. . . . ”, “B. . . . ”, and “C. . . . ” are displayed underneath as substrate treating conditions relating to the type of photoresist. When a photoresist solution “A. . . . ” is selected for application to wafer W, the operator touches the area of “A. . . . ” by way of substrate treating condition selection. Then the display mode of the touch panel 24 changes to what is shown in FIG. 14.

Step T5 (selection complete?)

Specifically, as shown in FIG. 14, the touch panel 24 displays a screen for confirmation of the substrate treating condition selection with a question “Selection complete?”. Under the question, answers “yes” and “no” are displayed.

When all substrate treating conditions have been selected for all the types, the operator touches the area of “yes” to complete the selecting operation, and the operation moves to step T6 for determining an optimal developing time. Then, the display mode of the touch panel 24 changes to what is shown in FIG. 15.

If all substrate treating conditions have not been selected, the operator touches the area of “no”, and the operation returns to step T3 for type selection. Then, the display mode of the touch panel 24 returns from FIG. 14 to FIG. 10. An arrangement may be made such that, when the area of “yes” is directly touched although all conditions have not been selected, the touch panel 24 displays “Selections are incomplete.” and returns to the display mode shown in FIG. 10.

When selecting a substrate treating condition based on a type other than the type of photoresist, the operator touches the area of “2. type of pattern size” or “3. type of pattern shape” shown in FIG. 10. When a substrate treating condition is selected from “2. type of pattern size”, the display mode of the touch panel 24 changes from FIG. 10 to FIG. 12. When a substrate treating condition is selected from “3. type of pattern shape”, the display mode of the touch panel 24 changes from FIG. 10 to FIG. 13.

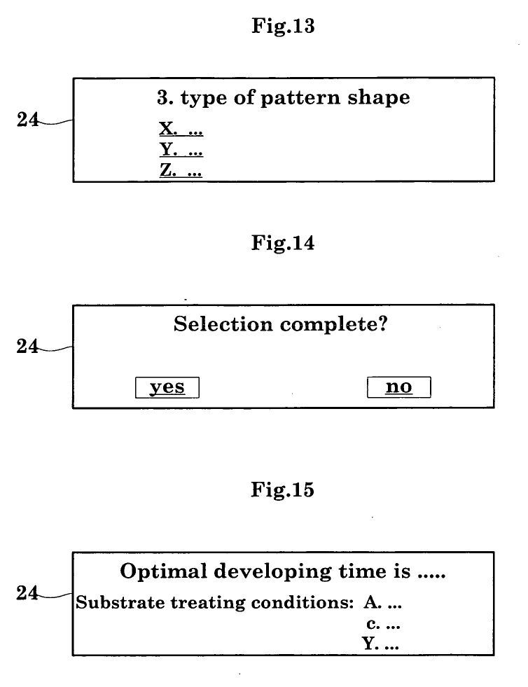

Specifically, when a substrate treating condition is selected from “2. type of pattern size”, as shown in FIG. 12, as in FIG. 11, the touch panel 24 displays a substrate treating condition selecting screen for “2. type of pattern size”. Options “a. . . . ”, “b. . . . ” and “c. . . . ” are displayed underneath as substrate treating conditions relating to the type of pattern size. When a substrate treating condition is selected from “3. type of pattern shape”, as shown in FIG. 13, the touch panel 24 displays a substrate treating condition selecting screen for “3. type of pattern shape”. Options “X. . . . ”, “Y. . . . ” and “Z. . . . ” are displayed underneath as substrate treating conditions relating to the type of pattern shape.

When, for example, exposure is performed with the pattern size “c. . . . ” and the pattern shape “Y. . . . ”, the operator touches the area of “c. . . . ” in FIG. 12 for selecting a substrate treating condition from the type of pattern size, and the area of “Y. . . . ” in FIG. 13 for selecting a substrate treating condition from the type of pattern shape. When a substrate treating condition is selected from the type of pattern size, the display mode of the touch panel 24 changes from FIG. 12 to FIG. 14. When a substrate treating condition is selected from the type of pattern shape, the display mode of the touch panel 24 changes from FIG. 13 to FIG. 14.

Step T6 (determine optimal developing time)

Specifically, when the display mode changes from FIGS. 12-14 to FIG. 15, an optimal developing time is derived from the substrate treating conditions selected in FIGS. 12-14 and correlations read from the correlation memory 22. The optimal developing time is displayed on the touch panel 24 as shown in FIG. 15. This optimal developing time is a developing time that produces zero pivotal shift with the substrate treating conditions selected in FIGS. 12-14 where the photoresist is “A. . . . ”, the pattern size “c. . . . ”, and the pattern shape “Y. . . . ”.

This optimal developing time is transmitted to the controller 21. Based on the optimal developing time, the controller 21 controls the adjusting valve 16 of the spin developer 12. This will particularly be described hereinafter in step S6.

Step T7 (start treatment)

Once this optimal developing time is displayed on the touch panel 24, treatment is started. Then, the operation moves to step S2. A series of substrate treating processes will be described hereinafter.

Step S2 (coating)

After the optimal developing time is set in step S1, a treatment for coating a wafer W with photoresist film is carried out in one of the spin coaters 8. Specifically, a cassette C is placed on the cassette table 5, and the indexer's transport mechanism, not shown, moves vertically, and horizontally on the transport path 6a in the directions indicated by the arrows in FIG. 1, and transfers one wafer W to be treated from the cassette C to the forward transport mechanism, not shown, in the processing unit 2. This transport mechanism moves vertically, and horizontally on the forward transport path 7 in the directions indicated by the arrows in FIG. 1, to transport the wafer W into one of the spin coaters 8.

At this time, the wafer W is placed and held in horizontal posture on the spin chuck 13 in the spin coater 8. The controller 21 rotates a motor portion of the spin chuck 13. With the rotation of the motor portion, the spin chuck 13 spins the wafer W in a horizontal plane. The controller 21 operates the adjusting valve 16 of the spin coater 8 to start delivery of the photoresist solution. The photoresist solution is delivered from the nozzle 14 toward the center of the wafer W held and spun by the spin chuck 13. The photoresist solution is spread from the center of the wafer W to form a photoresist film over the entire surface thereof. To end the coating treatment of the wafer W, the controller 21 stops rotation of the motor portion of the spin chuck 13, and operates the adjusting valve 16 in the spin coater 8 to stop the delivery of the photoresist solution.

Step S3 (prebake)

After the coating treatment of the wafer W, prebake treatment is carried out in the prebake unit 9. The prebake treatment is a pre-exposure heating treatment for evaporating the solvent in the photoresist film coating the wafer W. Specifically, the forward transport mechanism takes the coated wafer W out of the spin coater 8, and moves vertically, and horizontally on the forward transport path 7 in the directions indicated by the arrows in FIG. 1 to load the wafer W into the prebake unit 9.

At this time, the forward transport mechanism transfers and places the wafer W on the support pins, whereby the wafer W is held by the substrate holder 19. The controller 21 moves the shutter 18 along with the substrate holder 19 horizontally toward the heat-treating furnace 17. Then, the controller 21 operates the lamp unit 20 to emit light. The light travels through the light intake window of heat-treating furnace 17 to irradiate the wafer W in the heat-treating furnace 17 to perform prebake treatment or pre-exposure heating treatment. To end the prebake treatment, the controller 21 operates the lamp unit 20 to stop the light emission.

Step S4 (exposure)

After the prebake treatment of the wafer W, exposure is carried out in the exposing unit 4. Specifically, the controller 21 moves the shutter 18 along with the substrate holder 19 horizontally out of the heat-treating furnace 17 to unload the wafer W having undergone the prebake treatment, and transfers the wafer W from the support pins of the substrate holder 19 to the forward transport mechanism. This transport mechanism moves vertically, and horizontally on the forward transport path 7 in the direction indicated by an arrow in FIG. 1, and transfers the wafer W to the interface's transport mechanism not shown. This transport mechanism moves vertically, and horizontally on the interface's transport path 6b in the directions indicated by the arrows in FIG. 1 to transport the wafer W into the exposing unit 4. After the loading operation, the wafer W is exposed in the exposing unit 4.

Step S5 (postbake)

When the wafer W has been exposed, postbake treatment is carried out in the postbake unit 11. The postbake treatment is a post-exposure heating treatment for inducing a catalytic reaction from the acid produced in the photoresist film by exposure. Specifically, the interface's transport mechanism unloads the exposed wafer W from the exposing unit 4, and moves horizontally on the interface's transport path 6b in the directions indicated by the arrows in FIG. 1 to transfer the wafer W to the return transport mechanism not shown. This transport mechanism moves vertically, and horizontally on the return transport path 10 in the directions indicated by the arrows in FIG. 1 to load the wafer W into the postbake unit 11.

At this time, as in the prebake treatment in step S3, the controller 21 moves the shutter 18 along with the substrate holder 19 horizontally toward the heat-treating furnace 17. Then, as in the prebake treatment in step S3, the controller 21 operates the lamp unit 20 to irradiate the wafer W in the heat-treating furnace 17 to perform postbake treatment or post-exposure heating treatment.

Step S6 (development)

After the postbake treatment of the wafer W, development is carried out in one of the spin developers 12. Specifically, the return transport mechanism unloads the wafer W having undergone the postbake treatment from the postbake unit 11, and moves horizontally on the return transport path 10 in the directions indicated by the arrows in FIG. 1, to load the wafer W into one of the spin developers 12.

At this time, the wafer W is placed and held in horizontal posture on the spin chuck 13 in the spin developer 12. As in the coating treatment in step S2, the spin chuck 13 spins the wafer W in a horizontal plane. The adjusting valve 16 of the spin developer 12 is operated to start delivery of the developing solution. The developing solution is delivered from the nozzle 14 toward the center of the wafer W held and spun by the spin chuck 13 to perform development. To end the development of the wafer W, the controller 21 stops rotation of the motor portion of the spin chuck 13, and operates the adjusting valve 16 in the spin developer 12 to stop the delivery of the developing solution.

The time from start to finish of the delivery of the developing solution by the adjusting valve 16 corresponds to the developing time. In this embodiment, the controller 21 operates the adjusting valve 16, based on the optimal developing time determined in step T6, to bring the time from start to finish of the delivery of the developing solution into agreement with the optimal developing time.

After the wafer W is developed, the return transport mechanism takes the treated wafer W out of the spin developer 12, and moves vertically, and horizontally on the return transport path 10 in the directions indicated by the arrows in FIG. 1 to transfer the wafer W to the indexer's transport mechanism. This transport mechanism moves vertically, and horizontally on the indexer's transport path 6a in the directions indicated by the arrows in FIG. 1, and deposits the treated wafer W in the cassette C placed on the cassette table 5. After a plurality of (e.g. 25) treated wafers W are stored in the cassette C, the cassette C is transported out of the indexer 1 to complete the series of substrate treating processes.

The substrate treating method and apparatus in this embodiment having the above construction produce the following effects. A series of substrate treating processes is carried out based on a controlled developing time which is one of the substrate treating conditions relating to dissolving rate. This allows a pattern size to be set simply without manipulating a mask pattern. In this embodiment, the developing time is controlled by determining an optimal developing time in step T6. The series of substrate treating processes is carried out based on the controlled developing time, to bring the time from start to finish of the delivery of the developer into agreement with the optimal developing time. The adjusting valve 16 is operated in step S6 to perform development for a period corresponding to the optimal developing time.

As seen also from the schematic view of FIG. 5 showing a correlation between pivotal shift and developing time, with an extension of the developing time, the pivotal shift increases from the negative direction to become zero, and increases in the positive direction. The pattern size may be set by controlling the developing time to reduce the pivotal shift to zero, that is by determining an optimal developing time resulting in zero pivotal shift, without manipulating the mask pattern.

In this embodiment, the switching screen (FIG. 9) is displayed on the touch panel 24 for selecting whether to set a substrate treating condition according to a pivotal shift. Based on a substrate treating condition selected on the switching screen, treatment may be started (Step T7) and processes at steps S2 et seq. may be carried out. Alternatively, based on a substrate treating condition not selected on the switching screen, a regular treating process may be carried out (Step T2).

Further, the type selecting screen (FIG. 10) is displayed on the touch panel 24 for selecting types from the substrate treating conditions having combinations of the type of photoresist, the type of pattern size and the type of pattern shape. Then, a substrate treating condition selecting screen (FIGS. 11-13) is displayed on the touch panel 24 for selecting one substrate treating condition from a plurality of substrate treating conditions of the type selected on the type selecting screen.

In addition, the correlation memory 22 is provided for storing correlations between a plurality of substrate treating conditions, pivotal shifts, substrate treating conditions relating to acid diffusion and substrate treating conditions relating to dissolving rate. When the substrate treating conditions are switched on the switching screen, a correlation between the pivotal shift in the substrate treating condition selected on the substrate treating condition selecting screen and the substrate treating condition relating to acid diffusion or substrate treating condition relating to dissolving rate (developing time in this embodiment) is known from the selected substrate treating condition and the correlations read from the correlation memory 22. Based on the correlation between the pivotal shift and the substrate treating condition relating to acid diffusion or dissolving rate, it is possible to control the substrate treating condition relating to acid diffusion or substrate treating condition relating to dissolving rate (developing time in this embodiment). A pattern size may be set simply in a series of substrate treating processes. Thus, a substrate treating apparatus with increased flexibility is realized for executing a series of substrate treating processes, with a pattern size set simply.

This invention is not limited to the above embodiment, by may be modified as follows:

(1) The foregoing embodiment has been described with reference to the correlation between developing time and pivotal shift taken as an example of correlations stored in the correlation memory 22. Substrate treatment is carried out by controlling the developing time in the foregoing embodiment, but the invention is not limited to the control of developing time. The correlation memory 22 may store correlations between pivotal shift and substrate treating conditions relating to dissolving rate that influence the dissolving rate of the photoresist solution in development or substrate treating conditions relating to acid diffusion that influence diffusion of the acid produced by exposure of the photoresist solution. Substrate treatment may be carried out, according to this invention, by controlling the substrate treating conditions relating to dissolving rate or acid diffusion.

The substrate treating conditions relating to dissolving rate may, for example, include developing time as described in the embodiment, the temperature or humidity in a developing atmosphere (e.g. in the spin developers), and the concentration or temperature of the developing solution. The substrate treating conditions relating to acid diffusion may include substrate treating conditions relating to pre-exposure heating that influence pre-exposure heating (prebake), and substrate treating conditions relating to post-exposure heating that influence post-exposure heating (postbake). The substrate treating conditions relating to pre-exposure heating (prebake) may be a heating time or heating temperature of prebake treatment. The substrate treating conditions relating to post-exposure heating (postbake) may be a heating time or heating temperature of postbake treatment.

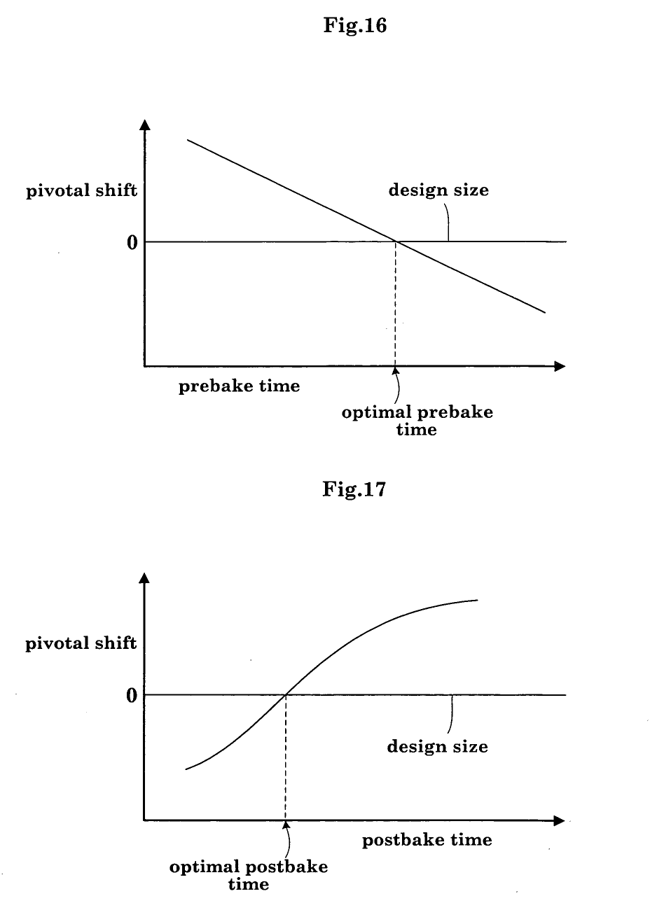

With an increase in the heating temperature in prebake treatment, wafers W are tightened, thereby hampering diffusion of the acid in time of exposure. In the case of the negative type, the pivotal shift decreases to zero and then increases in the negative direction. FIG. 16 shows a schematic view of a correlation between this heating temperature and pivotal shift. The horizontal axis represents the heating temperature in prebake treatment (prebake temperature in FIG. 16), and the vertical axis pattern size. The heating temperature at zero pivotal shift is an “optimal prebake temperature” shown in FIG. 16. As with FIG. 5 showing the schematic view of the correlation between developing time and pivotal shift in the described embodiment, when one substrate treating condition is selected from a plurality of substrate treating conditions for each of the various types of photoresist, pattern size and pattern shape, the schematic view shown in FIG. 16 is uniquely determined from that selected substrate treating condition.

With an increase in the heating temperature in postbake treatment, the acid produced by exposure promotes a catalytic reaction, and thus diffusion of the acid. In the case of the negative type, the pivotal shift increases from the negative direction to zero and then increases in the positive direction. FIG. 17 shows a schematic view of a correlation between this heating temperature and pivotal shift. The horizontal axis represents the heating temperature in postbake treatment (postbake temperature in FIG. 17), and the vertical axis pattern size. The heating temperature at zero pivotal shift is an “optimal postbake temperature” shown in FIG. 17. As with FIG. 5 showing the schematic view of the correlation between developing time and pivotal shift in the described embodiment, when one substrate treating condition is selected from a plurality of substrate treating conditions for each of the various types of photoresist, pattern size and pattern shape, the schematic view shown in FIG. 17 is uniquely determined from that selected substrate treating condition.

These substrate treating conditions may be set at any time before the treatment to be carried out with such treating conditions, instead of being limited to a particular time. The heating temperature in prebake treatment, for example, may be set at a coating time immediately preceding the prebake treatment, or may be before substrate treatment. The heating temperature in postbake treatment may be set at an exposing time immediately preceding the postbake treatment, or may be at a prebaking time before the exposure, or may be before substrate treatment. For controlling the substrate treating condition, e.g. the heating temperature in prebake or postbake treatment, the quantity of light from the lamp unit 20 may be adjusted by means of a filter or the like. For controlling the heating time, the timing of emitting light from the lamp unit 20 may be adjusted.

(2) In the foregoing embodiment, a substrate treating condition, typically developing time, is determined to reduce the pivotal shift to zero. Instead, substrate treatment may be carried out by controlling the mask pattern also, or by determining a substrate treating condition in which a pivotal shift causes little variation in pattern size. However, in order to set a pattern size without controlling the mask pattern, it is desirable to determine a substrate treating condition to reduce the pivotal shift to zero.

(3) In the foregoing embodiment, only one substrate treating condition, typically developing time, is controlled, and substrate treatment is carried out based on this controlled substrate treating condition. Instead, two or more substrate treating conditions may be controlled in combination according to a pivotal shift, to perform substrate treatment based on these controlled substrate treating conditions. For example, a substrate treating condition relating to acid diffusion and a substrate treating condition relating to dissolving rate may be controlled, to perform substrate treatment based on these controlled substrate treating conditions. It is possible to control a combination of heating times before and after the prebake treatment, among substrate treating conditions relating to acid diffusion, and to perform substrate treatment based on these controlled heating times.

(4) Results of treatment performed based on correlations read from the correlation memory 22 may be stored in the correlation memory 22, so that the results of treatment stored in the correlation memory 22 may be reflected on a next series of substrate treating processes. This provides advantages of accumulating data relating to the correlations, and storing data corrected for increased accuracy.

(5) In the foregoing embodiment, the input unit 23 is constructed to display, on the touch panel 24, the switching screen (FIG. 9) for selecting whether to set a substrate treating condition according to a pivotal shift, the type selecting screen (FIG. 10) for allowing selection of a type from among substrate treating conditions consisting of combinations of the types of photoresist, the types of pattern size and the types of pattern shape, and the substrate treating condition selecting screen (FIGS. 11-13) for selecting one substrate treating condition from a plurality of substrate treating conditions for the type selected on the type selecting screen. However, it is unnecessary to display all of the above screens on the touch panel 24.

Where, for example, substrate treating conditions are set according to pivotal shifts for all substrate treatments, the switching screen need not be displayed on the touch panel 24. That is, there is no need for the switching device in this invention. Where one type of photoresist and one type of pattern size are already provided and a selection is to be made from a plurality of substrate treating conditions relating to the type of pattern shape, the type selecting screen need not be displayed on the touch panel 24. That is, there is no need for the type selecting device in this invention. Where one type of photoresist, one type of pattern size and one type of pattern shape are already provided, the type selecting screen and substrate treating condition selecting screen need not be displayed on the touch panel 24. That is, there is no need for the type selecting device or substrate treating condition selecting device in this invention.

Apart from the touch panel 24, the keyboard 25, buttons 26 or the pointing device represented by a mouse may have functions corresponding to the switching device, type selecting device and substrate treating condition selecting device in this invention. Further, the invention is not limited to the display modes shown in FIGS. 6, 9-15. A plurality of types may be selected simultaneously.

(6) It is a chemically amplified resist as used in the embodiment, among coating solutions, that tends to cause a pivotal shift. Thus, a pattern size may be set simply. A coating solution other than a chemically amplified resist may be applied to the substrate treating apparatus according to this invention. Where a coating solution other than a chemically amplified resist is used, the operator may touch the area of “(2) not switch” on the switching screen displayed on the touch panel 24 shown in FIG. 9, thereby selecting not to set a substrate treating condition according to a pivotal shift. Where a chemically amplified resist is used, the operator may touch the area of “(1) switch” on the switching screen, thereby selecting to set a substrate treating condition according to a pivotal shift.

(7) The described coating treatment and developing treatment are carried out while spinning substrates. Instead, the substrates may be immersed in the developing solution. The coating film may be formed on the substrates by applying a coating solution to the substrates held still, or by transferring the film to the substrates.

The constructions of spin coaters 8, prebake unit 9, postbake unit 11 and spin developers 12 are not limited to those shown in FIGS. 2 and 3. The layout of indexer 1, processing unit 2, interface 3 and exposing unit 4 is of course not limited to what is shown in FIG. 1.

This invention may be embodied in other specific forms without departing from the spirit or essential attributes thereof and, accordingly, reference should be made to the appended claims, rather than to the foregoing specification, as indicating the scope of the invention.

What is claimed is:

1. A substrate treating method for performing a series of substrate treating processes to form a pattern on a substrate by forming a coating film of a chemically amplified photoresist on the substrate, exposing the substrate having the coating film formed thereon, and developing the exposed substrate, said method comprising the steps of:
controlling a substrate treating condition relating to acid diffusion that influences spread of an acid produced in said coating film by exposure of said coating film, according to a pivotal shift which is a difference between an actual pattern size and a mask pattern size, said actual pattern size being obtained from a processing carried out at a pivotal point which is an exposing condition resulting in little variation in pattern size even with variations in focus of exposing light; and
performing said series of substrate treating processes based on said substrate treating condition relating to acid diffusion as controlled.

2. A substrate treating method as defined in claim 1, wherein said substrate treating condition relating to acid diffusion is a substrate treating condition relating to pre-exposure heating that influences heating of the coating film before said exposure.

3. A substrate treating method as defined in claim 1, wherein said substrate treating condition relating to acid diffusion is a substrate treating condition relating to post-exposure heating that influences heating of the coating film after said exposure.

4. A substrate treating method as defined in claim 2, wherein said substrate treating condition relating to pre-exposure heating is a heating time of the coating film before said exposure, said series of substrate treating processes being performed based on said heating time as controlled.

5. A substrate treating method as defined in claim 2, wherein said substrate treating condition relating to pre-exposure heating is a heating temperature of the coating film before said exposure, said series of substrate treating processes being performed based on said heating temperature as controlled.

6. A substrate treating method as defined in claim 3, wherein said substrate treating condition relating to post-exposure heating is a heating time of the coating film after said exposure, said series of substrate treating processes being performed based on said heating time as controlled.

7. A substrate treating method as defined in claim 3, wherein said substrate treating condition relating to post-exposure heating is a heating temperature of the coating film after said exposure, said series of substrate treating processes being performed based on said heating temperature as controlled.

8. A substrate treating method as defined in claim 1, wherein said substrate treating condition relating to acid diffusion is controlled to reduce said pivotal shift to zero.

9. A substrate treating method for performing a series of substrate treating processes to form a pattern on a substrate by forming a coating film of a chemically amplified photoresist on the substrate, exposing the substrate having the coating film formed thereon, and developing the exposed substrate, said method comprising the steps of:
controlling a substrate treating condition relating to dissolving rate that influences a dissolving rate of said coating film by development, according to a pivotal shift which is a difference between an actual pattern size and a mask pattern size, said actual pattern size being obtained from a processing carried out at a pivotal point which is an exposing condition resulting in little variation in pattern size even with variations in focus of exposing light; and
performing said series of substrate treating processes based on said substrate treating condition relating to dissolving rate as controlled.

10. A substrate treating method as defined in claim 9, wherein said substrate treating condition relating to dissolving rate is a temperature in a developing atmosphere, said series of substrate treating processes being performed based on said temperature as controlled.

11. A substrate treating method as defined in claim 9, wherein said substrate treating condition relating to dissolving rate is a humidity in a developing atmosphere, said series of substrate treating processes being performed based on said humidity as controlled.

12. A substrate treating method as defined in claim 9, wherein said substrate treating condition relating to dissolving rate is a concentration of a developing solution, said series of substrate treating processes being performed based on said concentration as controlled.

13. A substrate treating method as defined in claim 9, wherein said substrate treating condition relating to dissolving rate is a temperature of a developing solution, said series of substrate treating processes being performed based on said temperature as controlled.

14. A substrate treating method as defined in claim 9, wherein said substrate treating condition relating to dissolving rate is a developing time, said series of substrate treating processes being performed based on said developing time as controlled.

15. A substrate treating method as defined in claim 9, wherein said substrate treating condition relating to dissolving rate is controlled to reduce said pivotal shift to zero.

16. A substrate treating method for performing a series of substrate treating processes to form a pattern on a substrate by forming a coating film of a chemically amplified photoresist on the substrate, exposing the substrate having the coating film formed thereon, and developing the exposed substrate, said method comprising the steps of:
controlling a substrate treating condition relating to acid diffusion that influences spread of an acid produced in said coating film by exposure of said coating film, according to a pivotal shift which is a difference between an actual pattern size and a mask pattern size, said actual pattern size being obtained from a processing carried out at a pivotal point which is an exposing condition resulting in little variation in pattern size even with variations in focus of exposing light, and controlling a substrate treating condition relating to dissolving rate that influences a dissolving rate of said coating film by development, according to said pivotal shift; and
performing said series of substrate treating processes based on said substrate treating condition relating to acid diffusion and said substrate treating condition relating to dissolving rate as controlled.

17. A substrate treating method as defined in claim 16, wherein said substrate treating condition relating to acid diffusion is a substrate treating condition relating to pre-exposure heating that influences heating of the coating film before said exposure.

18. A substrate treating method as defined in claim 16, wherein said substrate treating condition relating to acid diffusion is a substrate treating condition relating to post-exposure heating that influences heating of the coating film after said exposure.

19. A substrate treating method as defined in claim 17, wherein said substrate treating condition relating to pre-exposure heating is a heating time of the coating film before said exposure, said series of substrate treating processes being performed based on said heating time as controlled.

20. A substrate treating method as defined in claim 17, wherein said substrate treating condition relating to pre-exposure heating is a heating temperature of the coating film before said exposure, said series of substrate treating processes being performed based on said heating temperature as controlled.

21. A substrate treating method as defined in claim 18, wherein said substrate treating condition relating to post-exposure heating is a heating time of the coating film after said exposure, said series of substrate treating processes being performed based on said heating time as controlled.

22. A substrate treating method as defined in claim 18, wherein said substrate treating condition relating to post-exposure heating is a heating temperature of the coating film after said exposure, said series of substrate treating processes being performed based on said heating temperature as controlled.

23. A substrate treating method as defined in claim 16, wherein said substrate treating condition relating to dissolving rate is a temperature in a developing atmosphere, said series of substrate treating processes being performed based on said temperature as controlled.

24. A substrate treating method as defined in claim 16, wherein said substrate treating condition relating to dissolving rate is a humidity in a developing atmosphere, said series of substrate treating processes being performed based on said humidity as controlled.

25. A substrate treating method as defined in claim 16, wherein said substrate treating condition relating to dissolving rate is a concentration of a developing solution, said series of substrate treating processes being performed based on said concentration as controlled.

26. A substrate treating method as defined in claim 16, wherein said substrate treating condition relating to dissolving rate is a temperature of a developing solution, said series of substrate treating processes being performed based on said temperature as controlled.

27. A substrate treating method as defined in claim 16, wherein said substrate treating condition relating to dissolving rate is a developing time, said series of substrate treating processes being performed based on said developing time as controlled.

28. A substrate treating method as defined in claim 16, wherein said substrate treating condition relating to acid diffusion is controlled to reduce said pivotal shift to zero.

29. A substrate treating method as defined in claim 16, wherein said substrate treating condition relating to dissolving rate is controlled to reduce said pivotal shift to zero.

30. A substrate treating apparatus for performing a series of substrate treating processes to form a pattern on a substrate by forming a coating film on the substrate, exposing the substrate having the coating film formed thereon, and developing the exposed substrate, said apparatus comprising:
switching means for selecting whether to set a substrate treating condition according to a pivotal shift which is a difference between an actual pattern size and a mask pattern size, said actual pattern size being obtained from a processing carried out at a pivotal point which is an exposing condition resulting in little variation in pattern size even with variations in focus of exposing light;
wherein said series of substrate treating processes is performed based on said substrate treating condition selected or a substrate treating condition deselected by said switching means.

31. A substrate treating apparatus for performing a series of substrate treating processes to form a pattern on a substrate by forming a coating film on the substrate, exposing the substrate having the coating film formed thereon, and developing the exposed substrate, said apparatus comprising:
substrate treating condition selecting means for selecting one substrate treating condition from a plurality of substrate treating conditions of the same type; and
correlation storage means for storing correlations between a plurality of substrate treating conditions, a pivotal shift which is a difference between an actual pattern size and a mask pattern size, said actual pattern size being obtained from a processing carried out at a pivotal point which is an exposing condition resulting in little variation in pattern size even with variations in focus of exposing light, a substrate treating conditions relating to acid diffusion that influences spread of an acid produced in said coating film by exposure of said coating film, and a substrate treating condition relating to dissolving rate that influences a dissolving rate of said coating film by development;
wherein said series of substrate treating processes is performed based on said substrate treating condition selected by said substrate treating condition selecting means and said correlations read from said correlation storage means.

32. A substrate treating apparatus as defined in claim 31, wherein said type relates to a coating solution for forming said coating film on the substrate.

33. A substrate treating apparatus as defined in claim 31, wherein said type relates to pattern size.

34. A substrate treating apparatus as defined in claim 31, wherein said type relates to pattern form.

35. A substrate treating apparatus as defined in claim 31, wherein, after performing said series of substrate treating processes based on said correlation read from said correlation storage means, results of the processes are stored in said correlation storage means, to reflect said results of the processes on a next series of substrate treating processes.

36. A substrate treating apparatus for performing a series of substrate treating processes to form a pattern on a substrate by forming a coating film on the substrate, exposing the substrate having the coating film formed thereon, and developing the exposed substrate, said apparatus comprising:
type selecting means for selecting at least one type from different types of substrate treating conditions;
substrate treating condition selecting means for selecting one substrate treating condition from a plurality of substrate treating conditions of the same type selected by said type selecting means; and
correlation storage means for storing correlations between a plurality of substrate treating conditions, a pivotal shift which is a difference between an actual pattern size and a mask pattern size, said actual pattern size being obtained from a processing carried out at a pivotal point which is an exposing condition resulting in little variation in pattern size even with variations in focus of exposing light, a substrate treating condition relating to acid diffusion that influences spread of an acid produced in said coating film by exposure of said coating film, and a substrate treating condition relating to dissolving rate that influences a dissolving rate of said coating film by development;
wherein said series of substrate treating processes is performed based on said substrate treating condition selected by said substrate treating condition selecting means and said correlations read from said correlation storage means.

37. A substrate treating apparatus as defined in claim 36, wherein said type relates to a coating solution for forming said coating film on the substrate.

38. A substrate treating apparatus as defined in claim 36, wherein said type relates to pattern size.

39. A substrate treating apparatus as defined in claim 36, wherein said type relates to pattern form.

40. A substrate treating apparatus as defined in claim 36, wherein, after performing said series of substrate treating processes based on said correlation read from said correlation storage means, results of the processes are stored in said correlation storage means, to reflect said results of the processes on a next series of substrate treating processes.

41. A substrate treating apparatus for performing a series of substrate treating processes to form a pattern on a substrate by forming a coating film on the substrate, exposing the substrate having the coating film formed thereon, and developing the exposed substrate, said apparatus comprising:
switching means for selecting whether to set a substrate treating condition according to a pivotal shift which is a difference between an actual pattern size and a mask pattern size, said actual pattern size being obtained from a processing carried out at a pivotal point which is an exposing condition resulting in little variation in pattern size even with variations in focus of exposing light;
substrate treating condition selecting means for selecting one substrate treating condition from a plurality of substrate treating conditions of the same type; and
correlation storage means for storing correlations between a plurality of substrate treating conditions, said pivotal shift, a substrate treating condition relating to acid diffusion that influences spread of an acid produced in said coating film by exposure of said coating film, and a substrate treating condition relating to dissolving rate that influences a dissolving rate of said coating film by development;
wherein said series of substrate treating processes is performed based on said substrate treating condition selected or a substrate treating condition deselected by said switching means; and
wherein, when the substrate treating conditions are switched by said switching means, said series of substrate treating processes is performed based on said substrate treating condition selected by said substrate treating condition selecting means and said correlations read from said correlation storage means.

42. A substrate treating apparatus as defined in claim 41, wherein said type relates to a coating solution for forming said coating film on the substrate.

43. A substrate treating apparatus as defined in claim 41, wherein said type relates to pattern size.

44. A substrate treating apparatus as defined in claim 41, wherein said type relates to pattern form.

45. A substrate treating apparatus as defined in claim 41, wherein, after performing said series of substrate treating processes based on said correlation read from said correlation storage means, results of the processes are stored in said correlation storage means, to reflect said results of the processes on a next series of substrate treating processes.

46. A substrate treating apparatus for performing a series of substrate treating processes to form a pattern on a substrate by forming a coating film on the substrate, exposing the substrate having the coating film formed thereon, and developing the exposed substrate, said apparatus comprising:
switching means for selecting whether to set a substrate treating condition according to a pivotal shift which is a difference between an actual pattern size and a mask pattern size, said actual pattern size being obtained from a processing carried out at a pivotal point which is an exposing condition resulting in little variation in pattern size even with variations in focus of exposing light;
type selecting means for selecting at least one type from different types of substrate treating conditions;
substrate treating condition selecting means for selecting one substrate treating condition from a plurality of substrate treating conditions of the same type selected by said type selecting means; and
correlation storage means for storing correlations between a plurality of substrate treating conditions, said pivotal shift, a substrate treating condition relating to acid diffusion that influences spread of an acid produced in said coating film by exposure of said coating film, and a substrate treating condition relating to dissolving rate that influences a dissolving rate of said coating film by development;
wherein said series of substrate treating processes is performed based on said substrate treating condition selected or a substrate treating condition deselected by said switching means; and
wherein, when the substrate treating conditions are switched by said switching means, said series of substrate treating processes is performed based on said substrate treating condition selected by said substrate treating condition selecting means and said correlations read from said correlation storage means.

47. A substrate treating apparatus as defined in claim 46, wherein said type relates to a coating solution for forming said coating film on the substrate.

48. A substrate treating apparatus as defined in claim 46, wherein said type relates to pattern size.

49. A substrate treating apparatus as defined in claim 46, wherein said type relates to pattern form.

50. A substrate treating apparatus as defined in claim 46, wherein, after performing said series of substrate treating processes based on said correlations read from said correlation storage means, results of the processes are stored in said correlation storage means, to reflect said results of the processes on a next series of substrate treating processes.
